(19) United States
(12) Patent Application Publication
(10) Pub. No.: US 2026/0282306 A1
(43) Pub. Date: Sep. 17, 2026

(54) ELECTROMAGNETIC SHIELD

(71) Applicant: Mitsubishi Electric Corporation, Chiyoda-ku, Tokyo (JP)

(72) Inventor: Koichi FURUYA, Chiyoda-ku, Tokyo (JP)

(73) Assignee: Mitsubishi Electric Corporation, Chiyoda-ku, Tokyo (JP)

(21) Appl. No.: 19/168,310

(22) PCT Filed: Jun. 13, 2023
(86) PCT No.: PCT/JP2023/021815

§ 371 Date: Sep. 23, 2025

(51) Int. Cl. H05K 9/00

(52) U.S. Cl. CPC H05K 9/0081

(57) ABSTRACT

An electromagnetic shield includes: a plurality of substrates each having one or more conductors, in which out of the plurality of substrates, substrates adjacent to each other are supported in such a manner that the distance between a conductor of one of the adjacent substrates and a conductor of the other one of the adjacent substrates changes due to disturbance naturally present around the adjacent substrates.

### TECHNICAL FIELD

The present disclosure relates to an electromagnetic shield.

### BACKGROUND ART

There is a concern about information leakage due to interception of electromagnetic waves. For example, there are concerns about eavesdropping on communication via an electromagnetic wave of a specific frequency used for wireless communication and eavesdropping on information inside a device (for example, if a monitor is provided, a display image thereof or the like) via an electromagnetic wave of a specific frequency unintentionally emitted by an electronic device (so-called electromagnetic noise) (so-called TEMPEST).

As one of the countermeasures against the information leakage, there is known a method of reducing leakage of an electromagnetic wave to the outside by installing an electromagnetic shield on a wall, a window, or the like of a building. For example, Patent Literature 1 discloses a conventional electromagnetic shield.

### CITATION LIST

### Patent Literature

Patent Literature 1: JP 2017-188516 A

### SUMMARY OF INVENTION

### Technical Problem

The electromagnetic shield disclosed in Patent Literature 1 enables transmission or shielding of electromagnetic waves by using an elastic structure. In the electromagnetic shield disclosed in Patent Literature 1, an electromagnetic wave from a radio wave transmitter is shielded in a state where the elastic structure is not elastically deformed. Contrarily, in a state where the elastic structure is elastically deformed, the electromagnetic wave from the radio wave transmitter is transmitted. Therefore, in order to transmit or shield an electromagnetic wave in the electromagnetic shield disclosed in Patent Literature 1, it is necessary to artificially control the elastic structure. As a result, in a case where it is attempted to suppress information leakage due to interception of electromagnetic waves using the electromagnetic shield disclosed in Patent Literature 1, the control may be disadvantageously complicated.

The present invention has been made to solve the above-described disadvantageous problem, and an object of the invention is to provide an electromagnetic shield capable of modulating an electromagnetic wave without requiring artificial control.

### Solution to Problem

An electromagnetic shield according to the present disclosure includes: a plurality of substrates each having one or more conductors, the one or more conductors not entirely covering a surface of a corresponding one of the plurality of substrates, and out of the plurality of substrates, substrates adjacent to each other are supported in such a manner that a distance between a conductor of one of the adjacent substrates and a conductor of the other one of the adjacent substrates temporally changes due to disturbance naturally present around the adjacent substrates, and the electromagnetic shield modulates an electromagnetic wave transmitting through the adjacent substrates.

### Advantageous Effects of Invention

According to the present disclosure, electromagnetic waves can be modulated without requiring artificial control.

### BRIEF DESCRIPTION OF DRAWINGS

FIG. 1 is a perspective view of an electromagnetic shield according to a first embodiment.

FIG. 2 is an enlarged view of the main part of FIG. 1.

FIG. 3 is a conceptual diagram of the change in frequency characteristics of the complex transmission coefficient and is a diagram illustrating the change in the absolute value of the complex transmission coefficient.

FIG. 4 is a conceptual diagram of the change in frequency characteristics of the complex transmission coefficient and is a diagram illustrating the change in the argument of the complex transmission coefficient.

FIG. 5 is a perspective view of an electromagnetic shield according to a second embodiment.

FIG. 6 is an enlarged view of the main part of FIG. 5.

FIG. 7 is a perspective view of an electromagnetic shield according to a third embodiment.

FIG. 8 is an enlarged view of the main part of FIG. 7.

FIG. 9 is a perspective view of an electromagnetic shield according to a fourth embodiment.

FIG. 10 is an enlarged view of the main part of FIG. 9.

FIG. 11 is a perspective view of an electromagnetic shield according to a fifth embodiment.

FIG. 12 is an enlarged view of the main part of FIG. 11.

### DESCRIPTION OF EMBODIMENTS

To describe the present disclosure further in detail, embodiments for carrying out the present disclosure will be described below along with the accompanying drawings.

### First Embodiment

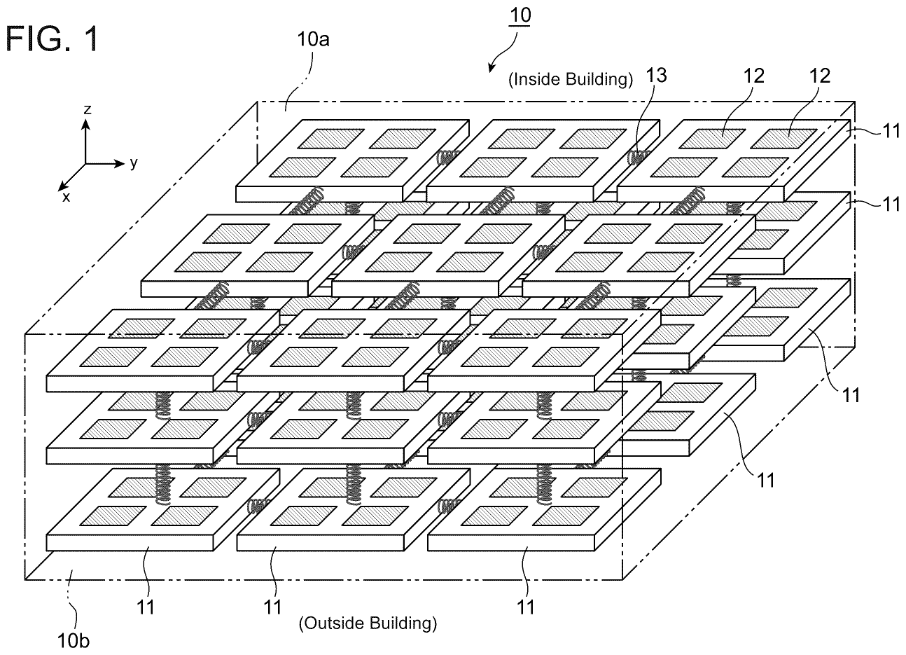

An electromagnetic shield 10 according to a first embodiment will be described with reference to FIGS. 1 to 4.

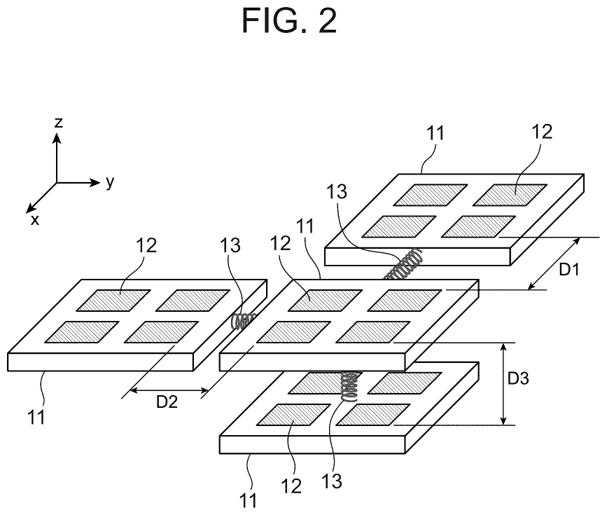

First, the structure of the electromagnetic shield 10 will be described with reference to FIGS. 1 and 2. FIG. 1 is a perspective view of the electromagnetic shield 10 according to the first embodiment. FIG. 2 is an enlarged view of the main part of FIG. 1.

An orthogonal coordinate system of a three-dimensional space in the electromagnetic shield 10 illustrated in FIG. 1 is defined by three x, y, and z axes orthogonal to each other in the space. FIG. 1 is an example in which the longitudinal direction of the electromagnetic shield 10 is set as an x-axis direction, the lateral direction (or width direction) of the electromagnetic shield 10 is set as a y-axis direction, and the height direction (or thickness direction) of the electromagnetic shield 10 is set as a z-axis direction. The arrows of the x axis, the y axis, and the z axis indicate respective positive directions.

The electromagnetic shield 10 illustrated in FIG. 1 is provided in such a manner as to separate the inside and the outside of a building, for example. The electromagnetic shield 10 has a flat inner surface 10a facing the inside of the building and a flat outer surface 10b facing the outside of the building. The inner surface 10a and the outer surface 10b are arranged in parallel to each other. Note that the electromagnetic shield 10 can be provided in a mobile object such as a vehicle, a railway, or an airplane other than a building.

In this example, a device that emits an electromagnetic wave including information to be prevented from leakage is provided inside the building. The device is, for example, a wireless device that emits an electromagnetic wave for wireless communication, an electronic device that emits electromagnetic noise, or the like. Meanwhile, there are cases where a reception device that can receive an electromagnetic wave including the information and eavesdrop on the information is disposed outside the building.

As illustrated in FIG. 1, the electromagnetic shield 10 includes a plurality of substrates 11 therein. All of the substrates 11 are arranged between the inner surface 10a and the outer surface 10b of the electromagnetic shield 10. The electromagnetic shield 10 is configured by forming one step parallel to an x-y plane from a plurality of substrates 11 arranged in the x-axis direction and a plurality of substrates 11 arranged in the y-axis direction and stacking a plurality of steps in the z-axis direction. In FIG. 1, one step parallel to the x-y plane includes three substrates 11 arranged in the x-axis direction and three substrates 11 arranged in the y-axis direction, and three steps are stacked in the z-axis direction.

All of the substrates 11 have the same shape and are periodically arranged. A substrate 11 has, for example, a rectangular shape. One substrate 11 includes one or more conductors 12. In addition, all of the conductors 12 have the same shape and are periodically arranged in one substrate 11. A conductor 12 has, for example, a rectangular shape.

FIG. 1 is an example in which one substrate 11 includes four conductors 12. In addition, although the substrate 11 and the conductor 12 are rectangular, the shape of the substrate 11 and the shape of the conductor 12 are not limited thereto. Furthermore, the shape of the substrate 11 and the shape of the conductor 12 may not be the same. For example, the substrate 11 and the conductor 12 may have a round shape, a rhombus shape, a triangular shape, or the like.

As illustrated in FIGS. 1 and 2, in the electromagnetic shield 10, substrates 11 adjacent to each other in the x-axis direction, the y-axis direction, or the z-axis direction are supported in such a manner that the distance between conductors 12 thereof changes due to disturbance that is naturally present around the electromagnetic shield 10 (around the substrates 11). Specifically, the substrates 11 adjacent to each other in the x-axis direction, the y-axis direction, or the z-axis direction are connected by an elastic body. FIGS. 1 and 2 are examples in which the elastic body is a spring 13. A first end of a spring 13 is connected to one substrate 11 out of two substrates 11 adjacent to each other, and a second end of the spring 13 is connected to the other substrate 11.

Note that the disturbance naturally present around the electromagnetic shield 10 is, for example, vibration, the wind, sound, or the like. The elastic body may be rubber.

In this example, substrates 11 adjacent to each other in the x-axis direction are arranged at an interval of a distance D1 in a state where a spring 13 is not expanded nor contracted. Furthermore, substrates 11 adjacent to each other in the y-axis direction are arranged at an interval of a distance D2 in a state where a spring 13 is not expanded nor contracted. Furthermore, substrates 11 adjacent to each other in the z-axis direction are arranged at an interval of a distance D3 in a state where a spring 13 is not expanded nor contracted. The distances D1, D2, and D3 are distances between conductors 12.

Therefore, since the electromagnetic shield 10 has the above-described structure and adjacent substrates 11 are connected by a spring 13, the substrates 11 also vibrate with vibration generated in the electromagnetic shield 10 and vibration generated in the building in which the electromagnetic shield 10 is installed.

The vibration of the building occurs in association with a natural phenomenon such as the wind or sound or an artificial phenomenon such as movement of a person or a mobile object outside the building. The vibration of the electromagnetic shield 10 is also generated with a wind pressure or a sound pressure directly applied to the electromagnetic shield 10. Such natural phenomena and artificial phenomena occur naturally and are not artificially controlled for the purpose of generating vibration in the electromagnetic shield 10.

Furthermore, since these vibrations are generated with factors of various vibrations contributing in a complicated manner, the magnitude, the frequency, and the generation direction thereof irregularly change depending on the installation position of the electromagnetic shield 10 and the time period. That is, the plurality of substrates 11 included in the electromagnetic shield 10 vibrates randomly depending on the time period and the installation position without requiring a power supply.

In this manner, with the vibration in the substrate 11 randomly occurring temporally and positionally, the distances D1, D2, and D3 between substrates 11 adjacent to each other also randomly change. At this point, a local complex transmission coefficient in a specific region of the electromagnetic shield 10 is dependent on the distances D1, D2, and D3 in the specific region. Note that the complex transmission coefficient indicates the amount of change in the amplitude and the phase of an electromagnetic wave when the electromagnetic wave is transmitted through the electromagnetic shield 10.

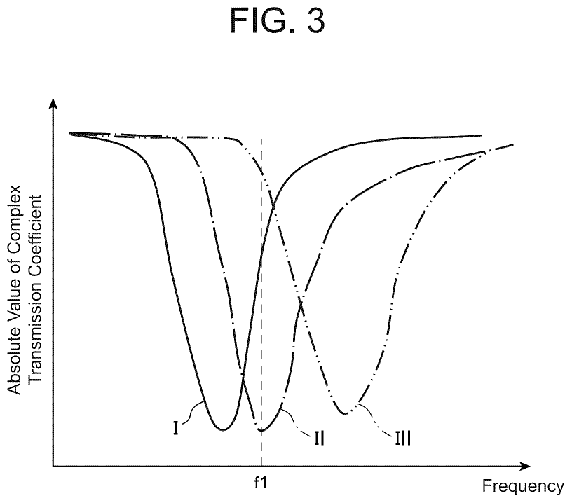

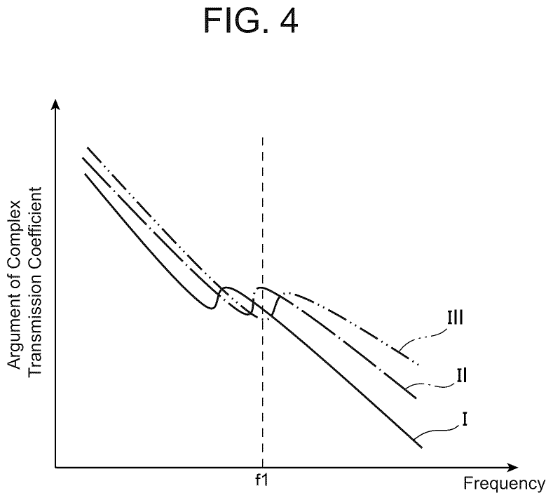

Next, the above-described points will be described with reference to FIGS. 3 and 4.

FIG. 3 is a conceptual diagram of the change in frequency characteristics of the complex transmission coefficient and is a diagram illustrating the change in the absolute value of the complex transmission coefficient (in other words, the transmission amplitude of an electromagnetic wave). FIG. 4 is a conceptual diagram of the change in frequency characteristics of the complex transmission coefficient and is a diagram illustrating the change in the argument of the complex transmission coefficient (in other words, the transmission phase of an electromagnetic wave). Note that frequency characteristics I, II, and III illustrated in FIGS. 3 and 4 are obtained by randomly extracting predetermined three combinations from among combinations of two or more values among the values of the distances D1, D2, and D3.

As illustrated in FIG. 3, when the distances D1, D2, and D3 change, the absolute value of the complex transmission coefficient changes depending on the magnitude of the frequency. For example, in a case where the frequency of an electromagnetic wave transmitting through the electromagnetic shield 10 is f1, the amplitude of the electromagnetic wave transmitted through the electromagnetic shield 10 varies for each of the frequency characteristics I, II, and III.

As illustrated in FIG. 4, when the distances D1, D2, and D3 change, the argument of the complex transmission coefficient changes depending on the magnitude of the frequency. For example, in the case where the frequency of the electromagnetic wave transmitting through the electromagnetic shield 10 is f1, the transmission phase of the electromagnetic wave transmitted through the electromagnetic shield 10 varies for each of the frequency characteristics I, II, and III.

Therefore, the electromagnetic wave incident on the electromagnetic shield 10 leaks to the outside of the building after the transmission amplitude and the transmission phase change depending on the transmission time and the transmission position. In other words, the electromagnetic wave incident on the electromagnetic shield 10 is modulated depending on the transmission time and the transmission position and leaks to the outside of the building.

Therefore, when an electromagnetic wave used for wireless communication and an electromagnetic wave (electromagnetic noise) emitted from an electronic device are incident on the electromagnetic shield 10, each of the electromagnetic waves is randomly modulated temporally and positionally by the electromagnetic shield 10. Therefore, information included in the electromagnetic wave becomes different from the original information before the electromagnetic wave is modulated and then is leaked to the outside of the building.

Therefore, the electromagnetic shield 10 can modulate the transmitting electromagnetic wave by disturbance such as vibration, the wind, and sound naturally present around the electromagnetic shield 10. As a result, even when a person who eavesdrops on the electromagnetic wave outside the building improves the reception sensitivity, the electromagnetic shield 10 can prevent information included in the original electromagnetic wave from being eavesdropped on.

Note that the substrates 11 and the conductors 12 may not be arranged periodically. Furthermore, the characteristics of the springs 13 may not be the same. In this case, the randomness of the modulation on an electromagnetic wave transmitting through the electromagnetic shield 10 can be further increased.

As described above, the electromagnetic shield 10 according to the first embodiment includes the plurality of substrates 11 each including one or more conductors 12, and out of the plurality of substrates 11, substrates 11 adjacent to each other are supported in such a manner that the distance between a conductor 12 of one of the adjacent substrates 11 and a conductor 12 of the other one of the adjacent substrates 11 changes due to disturbance naturally present around the adjacent substrates. Therefore, the electromagnetic shield 10 can modulate electromagnetic waves without requiring artificial control.

### Second Embodiment

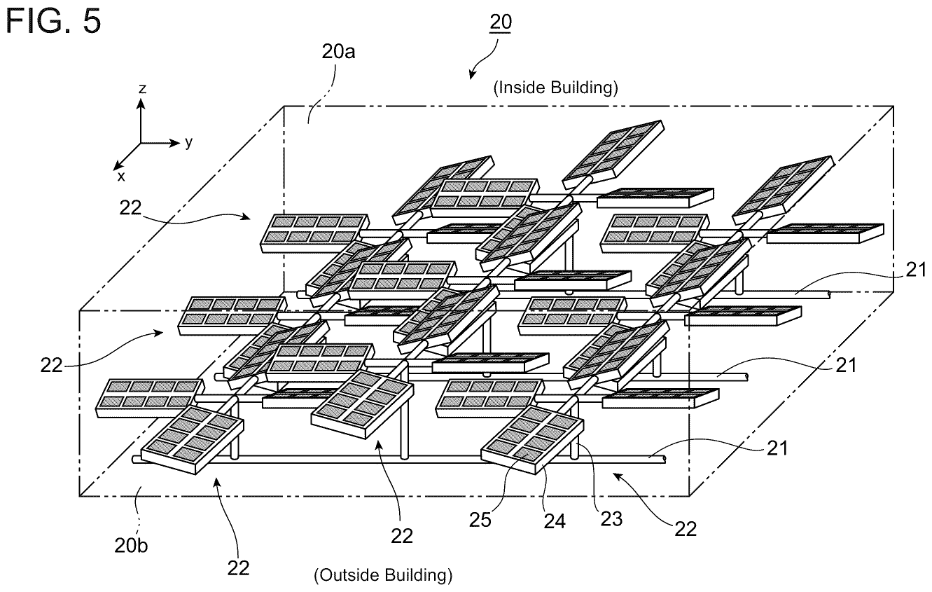

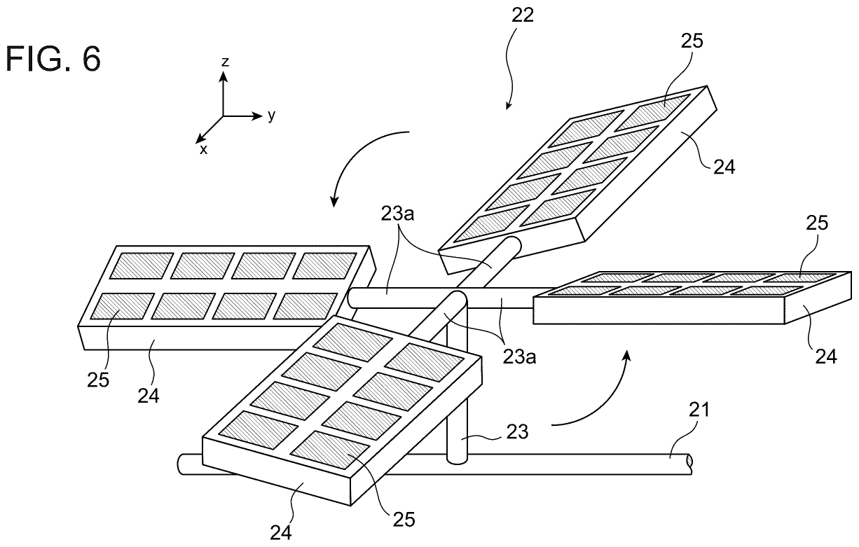

An electromagnetic shield 20 according to a second embodiment will be described with reference to FIGS. 5 and 6. FIG. 5 is a perspective view of the electromagnetic shield 20 according to the second embodiment. FIG. 6 is an enlarged view of the main part of FIG. 5.

The electromagnetic shield 10 according to the first embodiment illustrated in FIG. 1 is configured to modulate an electromagnetic wave by disturbance such as vibration, the wind, or a sound pressure by providing an elastic body between substrates 11 adjacent to each other. Meanwhile, the electromagnetic shield 20 according to the second embodiment illustrated in FIG. 5 modulates an electromagnetic wave by disturbance such as the wind by assembling a plurality of substrates 24 in a propeller shape.

As illustrated in FIG. 5, the electromagnetic shield 20 has a flat inner surface 20a facing the inside of a building and a flat outer surface 20b facing the outside of the building. The inner surface 20a and the outer surface 20b are arranged in parallel to each other. The electromagnetic shield 20 further includes a plurality of fixing members 21 and a plurality of propellers 22 therein. All of the fixing members 21 and all of the propellers 22 are arranged between the inner surface 20a and the outer surface 20b. The x-y plane, the inner surface 20a, and the outer surface 20b constitute reference planes.

The fixing members 21 are fixed to the outer surface 20b side, for example. A fixing member 21 has a shaft shape and is disposed in such a manner as to extend in the y-axis direction. One or more propellers 22 are rotatably supported by each of the fixing members 21. FIG. 5 is an example in which three fixing members 21 are provided, and three propellers 22 are rotatably supported by each of the fixing members 21.

As illustrated in FIGS. 5 and 6, a propeller 22 includes, for example, a rotation shaft 23, substrates 24, and conductors 25. The arrows illustrated in FIG. 6 indicate the rotation direction of the propeller 22.

The rotation shaft 23 is disposed in such a manner as to be orthogonal to the length direction of the fixing member 21. The rotation shaft 23 is also disposed in such a manner as to extend in the Z-axis direction. The proximal end of the rotation shaft 23 is rotatably supported by the fixing member 21 with the axial center thereof being the rotation center. Meanwhile, the distal end of the rotation shaft 23 is a free end. The rotation shaft 23 has a plurality of branch shafts 23a. Each of the branch shafts 23a is provided radially from the distal end of the rotation shaft 23.

A substrate 24 is provided at the distal end of each of the branch shafts 23a. The substrates 24 constitute blades of the propeller 22. The substrates 24 are arranged in such a manner that the front surface and the back surface thereof are inclined with respect to the x-y plane. All of the substrates 24 have the same shape. The substrates 24 have, for example, a rectangular shape.

One substrate 24 includes a plurality of conductors 25. All of the conductors 25 have the same shape and are periodically arranged on one substrate 24. The conductors 25 have, for example, a rectangular shape. In addition, a conductor 25 is provided on a substrate 24 in such a manner that the front surface thereof is inclined with respect to the x-y plane.

That is, the substrates 24 are supported at constant intervals around the axial center of the rotation shaft 23 in such a manner that the conductors 25 are inclined with respect to the x-y plane serving as the reference plane. Therefore, a substrate 24 is rotatable in such a manner that distances between the conductors 25 of the substrate 24 and the conductors 25 of the other substrates 24 supported by the rotation shaft 23 change due to disturbance naturally present around the electromagnetic shield 20 (around the substrates 24). Note that the disturbance naturally present around the electromagnetic shield 20 is, for example, the wind or the like.

FIG. 5 is an example in which one propeller 22 includes four substrates 24 each having eight conductors 25. Note that, in the electromagnetic shield 20, the number of installed propellers 22, the number of substrates 24 installed in one propeller 22, and the number of conductors 25 installed in one substrate 24 can be adjusted as appropriate.

Therefore, with the electromagnetic shield 20 having the above-described structure, the propellers 22 rotate when the wind hits the substrates 24 forming the blades of the propellers 22.

The wind blown onto the electromagnetic shield 20 is generated in association with a natural phenomenon such as the wind or rain or an artificial phenomenon such as movement of a person or a mobile object outside the building. Moreover, in a case where the electromagnetic shield 20 is provided on a mobile object, wind generated as the mobile object travels also acts on the electromagnetic shield 20. Such natural phenomena and artificial phenomena occur naturally and are not artificially controlled for the purpose of blowing wind to the electromagnetic shield 20.

Furthermore, the directions and speeds of the phenomena are determined by various conditions such as weather conditions and arrangement of surrounding objects contributing in a complicated manner. In a case where the electromagnetic shield 20 is provided on a mobile object, the traveling speed and the traveling direction of the mobile object contribute in addition to the above. Therefore, the direction and the speed of the wind blown to the electromagnetic shield 20 irregularly change depending on the installation position of the electromagnetic shield 20 and the time period. That is, the propellers 22 included in the electromagnetic shield 20 rotate at random rotation speeds depending on the time period and an installation position without requiring a power supply.

As described above, the rotation of the propellers 22 randomly occurs temporally and positionally, whereby the distance, the facing angle, and the overlapping area randomly change between conductors 25 of substrates 24 in a propeller 22 and conductors 25 of substrates 24 in a propeller 22 adjacent to the propeller 22. At this point, a local complex transmission coefficient in a specific region of the electromagnetic shield 20 is dependent on the distance, the facing angle, and the overlapping area in the specific region.

Therefore, the electromagnetic wave incident on the electromagnetic shield 20 leaks to the outside of the building after the transmission amplitude and the transmission phase change depending on the transmission time and the transmission position. In other words, the electromagnetic wave incident on the electromagnetic shield 10 is modulated depending on the transmission time and the transmission position and leaks to the outside of the building.

Therefore, when an electromagnetic wave used for wireless communication and an electromagnetic wave (electromagnetic noise) emitted from an electronic device are incident on the electromagnetic shield 20, each of the electromagnetic waves is randomly modulated temporally and positionally by the electromagnetic shield 20. Therefore, information included in the electromagnetic wave becomes different from the original information before the electromagnetic wave is modulated and then is leaked to the outside of the building.

Therefore, the electromagnetic shield 20 can modulate the transmitting electromagnetic wave by disturbance such as the wind naturally present around the electromagnetic shield 20. As a result, even when a person who eavesdrops on the electromagnetic wave outside the building improves the reception sensitivity, the electromagnetic shield 20 can prevent information included in the original electromagnetic wave from being eavesdropped on.

Note that the propellers 22 and the conductors 25 may not be arranged periodically. In addition, the number of substrates 24 installed for one propeller 22, the number of conductors 25 installed in one substrate 24, the inclination angles of the front surface and the back surface of the substrates 24 with respect to the x-y plane, the shapes of the substrates 24, and the shapes of the conductors 25 may not be the same. In this case, the randomness of the modulation on an electromagnetic wave transmitting through the electromagnetic shield 20 can be further increased.

As described above, the electromagnetic shield 20 according to the second embodiment includes: a substrate 24 having one or more conductors 25; and the plurality of rotation shafts 23 that each support the substrate 24 around the axial center in a state where the conductors 25 are inclined with respect to the reference plane, in which the substrate 24 rotates in such a manner that the distance between a conductor 25 of the substrate 24 and a conductor 25 of a substrate 24 supported by another rotation shaft 23 changes due to disturbance naturally present around the substrate. Therefore, the electromagnetic shield 20 can modulate electromagnetic waves without requiring artificial control.

### Third Embodiment

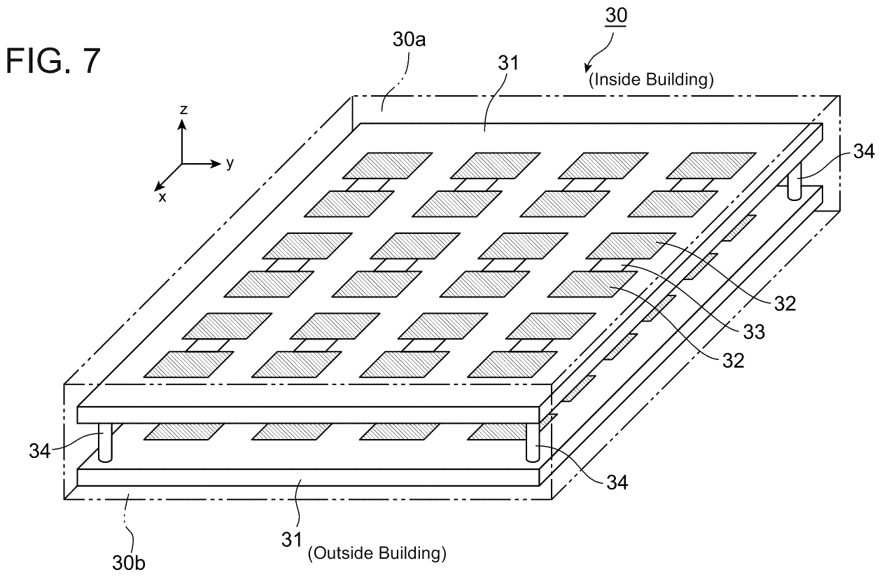

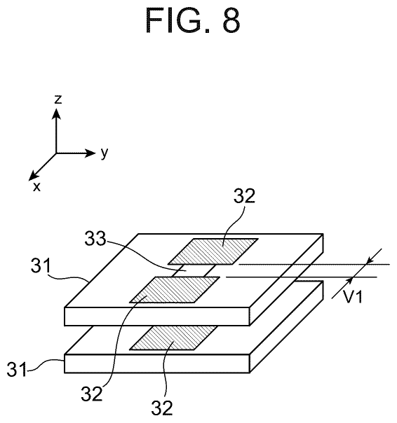

An electromagnetic shield 30 according to a third embodiment will be described with reference to FIGS. 7 and 8. FIG. 7 is a perspective view of the electromagnetic shield 30 according to the third embodiment. FIG. 8 is an enlarged view of the main part of FIG. 7.

The electromagnetic shields 10 and 20 according to the first and second embodiments illustrated in FIGS. 1 and 5 are structured to modulate an electromagnetic wave by disturbance such as vibration, the wind, or sound. Meanwhile, the electromagnetic shield 30 according to the third embodiment illustrated in FIG. 7 modulates an electromagnetic wave by an electromagnetic field that is a physical phenomenon other than the above.

As illustrated in FIG. 7, the electromagnetic shield 30 has a flat inner surface 30a facing the inside of a building and a flat outer surface 30b facing the outside of the building. The inner surface 30a and the outer surface 30b are arranged in parallel to each other. The electromagnetic shield 30 further includes a plurality of substrates 31, a plurality of conductors 32, a plurality of varactors 33, and a plurality of support members 34 therein. The plurality of substrates 31, the plurality of conductors 32, the plurality of varactors 33, and the plurality of support members 34 are arranged between the inner surface 30a and the outer surface 30b.

The substrates 31 are stacked in the z-axis direction. In this case, the z-axis direction is the stacking direction. The substrates 31 adjacent to each other in the z-axis direction are connected to each other via the support members 34. The support members 34 connect four corners on the back surface of one of the adjacent substrates 31 and respective four corners on the front surface of the other one of the adjacent substrates 31. Therefore, the plurality of substrates 31 are stacked at a certain interval by the support members 34. Note that the substrates 31 may not be stacked at regular intervals. Furthermore, only one substrate 31 may be provided.

As illustrated in FIGS. 7 and 8, one substrate 31 includes a plurality of conductors 32. All of the conductors 32 have the same shape and are periodically arranged on one substrate 31. Specifically, one substrate 31 includes one or more pairs of conductors 32.

A varactor 33 connects a pair of conductors 32 therebetween. The varactors 33 are provided on the front surface of the substrate 31. A varactor 33 constitutes a coupling member. The varactors 33 have a characteristic that the electrostatic capacitance value changes depending on the value of the applied voltage. Furthermore, the capacitance of the varactors 33, which is a physical property, changes due to disturbance naturally present around the electromagnetic shield 30 (around the substrates 31). At this point, the disturbance naturally present around the electromagnetic shield 30 is, for example, an electromagnetic field.

FIG. 7 illustrates an example in which two substrates 31 are stacked, and twelve pairs of conductors 32, each of the pairs connected by one varactor 33, are provided for each of the substrates 31. Note that, in the electromagnetic shield 30, the number of stacked substrates 31, the number of pairs of conductors 32 provided for one substrate 31, and the number of installed varactors 33 between a pair of conductors 32 can be adjusted as appropriate.

Therefore, with the above-described configuration, the electromagnetic shield 30 generates an electric field and a voltage V1 associated with the electric field between a pair of conductors 32 connected by a varactor 33 by an electromagnetic field naturally present around the electromagnetic shield 30.

The electromagnetic field naturally present around the electromagnetic shield 30 is generated by an electromagnetic wave for wireless communication radiated by a wireless device, an electromagnetic wave (electromagnetic noise) emitted by an electronic device, electromagnetic waves of various other devices, electromagnetic waves due to electrostatic discharge caused by approach between human bodies or objects, or others. Such a phenomenon of generation of an electromagnetic field occurs naturally and is not artificially controlled for the purpose of generating the electric field and the voltage V1 associated with the electric field in the electromagnetic shield 30.

Furthermore, the frequency spectrum, the polarization, and the direction of arrival of each of these electromagnetic waves are determined by various conditions, such as the positional relationships between the radiation sources of the electromagnetic waves and the electromagnetic shield 30 and arrangement of objects present on the propagation paths of the electromagnetic waves from the radiation sources (devices) to the electromagnetic shield 30, contributing in a complicated manner. Therefore, the frequency spectrum, the polarization, and the direction of arrival of each of the electromagnetic waves irregularly change depending on the installation position of the electromagnetic shield 30 and the time period. That is, the voltage V1 generated in the electromagnetic shield 30 randomly changes depending on the time period and the installation position without requiring a power supply.

As described above, the voltage V1 generated in the electromagnetic shield 30 randomly changes temporally and positionally, whereby the electrostatic capacitance of the varactors 33 also randomly changes. At this point, a local complex transmission coefficient in a specific region of the electromagnetic shield 30 is dependent on the voltage V1 in the specific region.

Therefore, the electromagnetic wave incident on the electromagnetic shield 30 leaks to the outside of the building after the transmission amplitude and the transmission phase change depending on the transmission time and the transmission position. In other words, the electromagnetic wave incident on the electromagnetic shield 30 is modulated depending on the transmission time and the transmission position and then leaks to the outside of the building.

Therefore, when an electromagnetic wave used for wireless communication and an electromagnetic wave (electromagnetic noise) emitted from an electronic device are incident on the electromagnetic shield 30, each of the electromagnetic waves is randomly modulated temporally and positionally by the electromagnetic shield 30. Therefore, information included in the electromagnetic wave becomes different from the original information before the electromagnetic wave is modulated and then is leaked to the outside of the building.

Therefore, the electromagnetic shield 30 can modulate the transmitting electromagnetic wave by disturbance such as an electromagnetic wave naturally present around the electromagnetic shield 30. As a result, even when a person who eavesdrops on the electromagnetic wave outside the building improves the reception sensitivity, the electromagnetic shield 30 can prevent information included in the original electromagnetic wave from being eavesdropped on.

Note that the conductors 32 may not be arranged periodically. In addition, the shapes of the substrates 31, the shapes of the conductors 32, the shapes of the varactors 33, and the characteristics of the varactors 33 may not be the same. In this case, the randomness of the modulation on an electromagnetic wave transmitting through the electromagnetic shield 30 can be further increased.

As described above, the electromagnetic shield 30 according to the third embodiment includes: one or more substrates 31 each having one or more pairs of conductors 32; and a varactor 33 that couples each of the one or more pairs of conductors 32 and changes in physical properties due to disturbance naturally present around the substrates. Therefore, the electromagnetic shield 30 can modulate electromagnetic waves without requiring artificial control.

### Fourth Embodiment

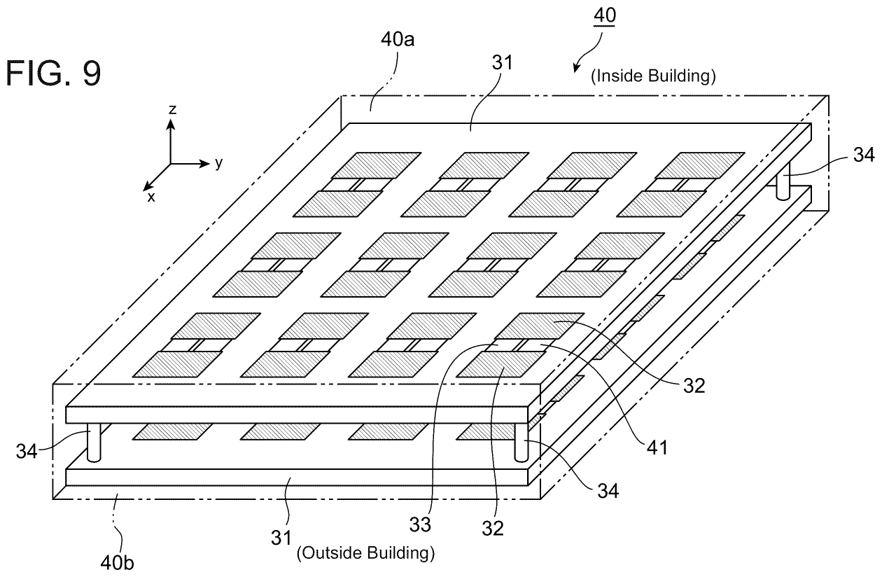

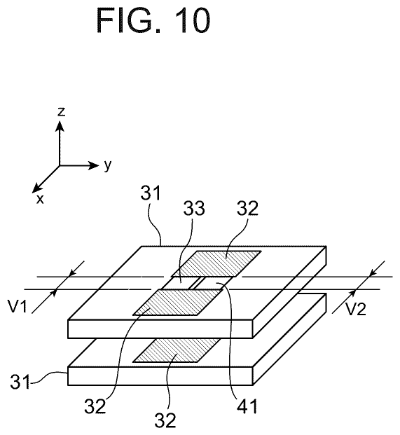

An electromagnetic shield 40 according to a fourth embodiment will be described with reference to FIGS. 9 and 10. FIG. 9 is a perspective view of the electromagnetic shield 40 according to the fourth embodiment. FIG. 10 is an enlarged view of the main part of FIG. 9. Note that the same symbols are given to components having similar functions as those described in the third embodiment, and description thereof will be omitted.

In the electromagnetic shield 30 according to the third embodiment illustrated in FIG. 7, an electromagnetic wave is modulated by the electromagnetic field that is a physical phenomenon. Meanwhile, the electromagnetic shield 40 according to the fourth embodiment illustrated in FIG. 9 modulates an electromagnetic wave by an electromagnetic field and light, vibration, heat, or the like that is another physical phenomenon. That is, the electromagnetic shield 40 according to the fourth embodiment modulates an electromagnetic wave by two types of physical phenomena different from each other.

As illustrated in FIG. 9, the electromagnetic shield 40 has a flat inner surface 40a facing the inside of a building and a flat outer surface 40b facing the outside of the building. The inner surface 40a and the outer surface 40b are arranged in parallel to each other. The electromagnetic shield 40 further includes a plurality of substrates 31, a plurality of conductors 32, a plurality of varactors 33, and a plurality of environmental power generation elements 41 therein. The plurality of substrates 31, the plurality of conductors 32, the plurality of varactors 33, and the plurality of environmental power generation elements 41 are arranged between the inner surface 40a and the outer surface 40b. The electromagnetic shield 40 is obtained by adding environmental power generation elements 41, which serve as coupling members, to the configuration of the electromagnetic shield 30.

As illustrated in FIGS. 9 and 10, a pair of conductors 32 is connected by a varactor 33 and an environmental power generation element 41. The environmental power generation elements 41 are provided on the front surface of a substrate 31. The environmental power generation elements 41 have a characteristic that the power generation amount changes depending on the energy such as light, vibration, or heat. That is, in the environmental power generation elements 41, the amount of power generation, which is a physical property, changes due to disturbance naturally present around the electromagnetic shield 40 (around the substrates 31). At this point, the disturbance naturally present around the electromagnetic shield 40 is, for example, any one of light, vibration, or heat.

FIG. 9 illustrates an example in which two substrates 31 are stacked, and twelve pairs of conductors 32, each of the pairs connected by one varactor 33 and one environmental power generation element 41, are provided for each of the substrates 31. Note that, in the electromagnetic shield 40, the number of stacked substrates 31, the number of pairs of conductors 32 provided for one substrate 31, the number of installed varactors 33 and the number of installed environmental power generation elements 41 between a pair of conductors 32 can be adjusted as appropriate.

The following operation of the electromagnetic shield 40 will be described with a case where the environmental power generation elements 41 receive light to generate power. Even in cases where the environmental power generation elements 41 generate power by receiving vibration, heat, or the like, the operation is the same.

Therefore, with the electromagnetic shield 40 having the above-described configuration, an electric field and a voltage V1 associated with the electric field are generated between a pair of conductors 32 connected by a varactor 33 by an electromagnetic field naturally present around the electromagnetic shield 40. In addition, with the electromagnetic shield 40 having the above-described configuration, an environmental power generation element 41 generates power with light naturally present around the electromagnetic shield 40, whereby a voltage V2 associated with this power generation is generated between a pair of conductors 32 connected by the environmental power generation element 41.

The light naturally present around the electromagnetic shield 40 includes natural phenomena such as sunlight and artificial phenomena such as light emitted from a television monitor. Such natural phenomena and artificial phenomena occur naturally and are not artificially controlled for the purpose of emitting light to the electromagnetic shield 40.

Furthermore, the intensity of light naturally present around the electromagnetic shield 40 and the voltage V2 generated depending on the intensity of the light in the environmental power generation element 41 are determined by various conditions, such as the positional relationship between the radiation source (light source) of the light and the electromagnetic shield 40 and the arrangement of objects present on the propagation path of the light from the radiation source to the electromagnetic shield 40, contributing in a complicated manner. Therefore, the intensity of the light and the voltage V2 irregularly change depending on the installation position of the electromagnetic shield 40 and the time period. That is, the voltage V2 generated in the electromagnetic shield 40 randomly changes depending on the time period and the installation position without requiring a power supply.

As described above, the power generation amount of the environmental power generation element 41 randomly changes temporally and positionally, whereby the voltage V2 generated between the pair of conductors 32 also randomly changes. At this point, a local complex transmission coefficient in a specific region of the electromagnetic shield 40 is dependent on the voltage V2 in the specific region.

Therefore, the electromagnetic wave incident on the electromagnetic shield 40 leaks to the outside of the building after the transmission amplitude and the transmission phase change depending on the transmission time and the transmission position. In other words, the electromagnetic wave incident on the electromagnetic shield 40 is modulated depending on the transmission time and the transmission position and leaks to the outside of the building.

Therefore, when an electromagnetic wave used for wireless communication and an electromagnetic wave (electromagnetic noise) emitted from an electronic device are incident on the electromagnetic shield 40, each of the electromagnetic waves is randomly modulated temporally and positionally by the electromagnetic shield 40. Therefore, information included in the electromagnetic wave becomes different from the original information before the electromagnetic wave is modulated and then is leaked to the outside of the building.

Therefore, the electromagnetic shield 40 can modulate the transmitting electromagnetic wave by disturbance such as light, vibration, and heat naturally present around the electromagnetic shield 40. As a result, even when a person who eavesdrops on the electromagnetic wave outside the building improves the reception sensitivity, the electromagnetic shield 40 can prevent information included in the original electromagnetic wave from being eavesdropped on.

Note that the pairs of conductors 32 connected by the varactors 33 and the environmental power generation elements 41 may not be arranged periodically. In addition, the shapes and characteristics of the environmental power generation elements 41 and the varactors 33 may not be the same. In this case, the randomness of the modulation on an electromagnetic wave transmitting through the electromagnetic shield 40 can be further increased.

As described above, the electromagnetic shield 40 according to the fourth embodiment includes: one or more substrates 31 each having one or more pairs of conductors 32; and an environmental power generation element 41 that couples each of the one or more pairs of conductors 32 and changes in physical properties due to disturbance naturally present around the substrates. Therefore, the electromagnetic shield 40 can modulate electromagnetic waves without requiring artificial control.

### Fifth Embodiment

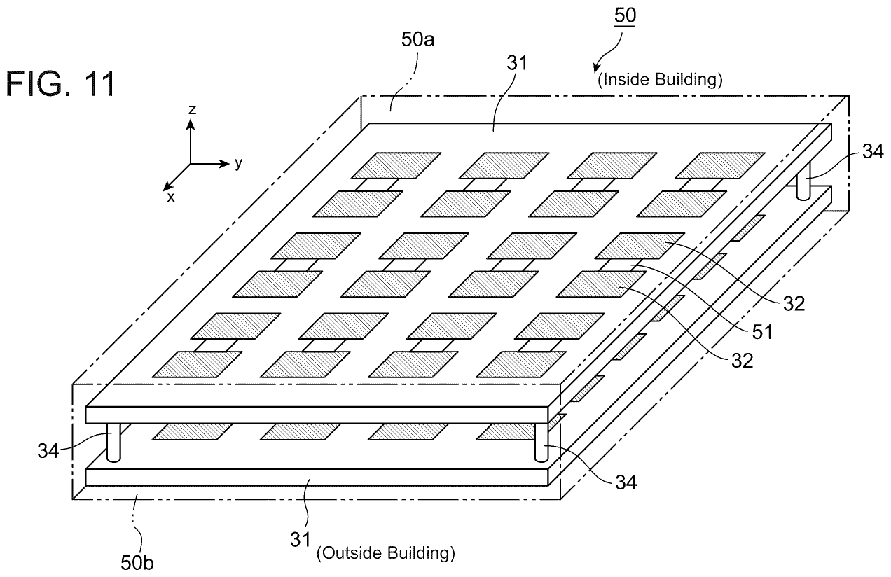

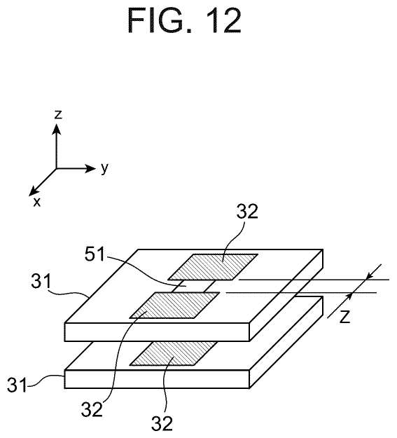

An electromagnetic shield 50 according to a fifth embodiment will be described with reference to FIGS. 11 and 12. FIG. 11 is a perspective view of the electromagnetic shield 50 according to the fifth embodiment. FIG. 12 is an enlarged view of the main part of FIG. 11. Note that the same symbols are given to components having similar functions as those described in the third embodiment, and description thereof will be omitted.

In the electromagnetic shield 30 according to the third embodiment illustrated in FIG. 7, an electromagnetic wave is modulated by the electromagnetic field that is a physical phenomenon. Meanwhile, the electromagnetic shield 50 according to the fifth embodiment illustrated in FIG. 11 modulates an electromagnetic wave by light, temperature, sound, or others that are physical phenomena.

As illustrated in FIG. 11, the electromagnetic shield 50 has a flat inner surface 50a facing the inside of a building and a flat outer surface 50b facing the outside of the building. The inner surface 50a and the outer surface 50b are arranged in parallel to each other. The electromagnetic shield 50 further includes a plurality of substrates 31, a plurality of conductors 32, and a plurality of sensors 51 therein. The plurality of substrates 31, the plurality of conductors 32, and the plurality of sensors 51 are arranged between the inner surface 50a and the outer surface 50b. The electromagnetic shield 50 includes a sensor 51 serving as a coupling member instead of a varactor 33 of the electromagnetic shield 30.

As illustrated in FIGS. 11 and 12, a pair of conductors 32 is connected by a sensor 51. The sensor 51 is provided on the front surface of a substrate 31. The sensor 51 detects the intensity of light, the temperature, the sound pressure, or others and has a characteristic that an electrical impedance Z changes depending on these. That is, in the sensors 51, the impedance Z, which is a physical property, changes due to disturbance naturally present around the electromagnetic shield 50 (around the substrates 31). For example, in a case where the sensor 51 is an optical sensor, the disturbance is light. Alternatively, in a case where the sensor 51 is a temperature sensor, the disturbance is temperature. Further alternatively, in a case where the sensor 51 is a sound sensor, the disturbance is sound.

FIG. 11 illustrates an example in which two substrates 31 are stacked, and twelve pairs of conductors 32, each of the pairs connected by one sensor 51, are provided for each of the substrates 31. Note that, in the electromagnetic shield 50, the number of stacked substrates 31, the number of pairs of conductors 32 provided for one substrate 31, and the number of installed sensors 51 between a pair of conductors 32 can be adjusted as appropriate.

The following operation of the electromagnetic shield 50 will be described with a case where the sensors 51 are optical sensors. Even in cases where the sensors 51 are temperature sensors or sound sensors, the operation is the same.

Therefore, with the electromagnetic shield 50 having the above-described configuration, a sensor 51 connecting a pair of conductors 32 detects light naturally present around the electromagnetic shield 50, whereby the impedance Z is generated inside the sensor 51.

The light naturally present around the electromagnetic shield 50 includes natural phenomena such as sunlight and artificial phenomena such as light emitted from a television monitor. Such natural phenomena and artificial phenomena occur naturally and are not artificially controlled for the purpose of emitting light to the electromagnetic shield 50.

Furthermore, the intensity of light naturally present around the electromagnetic shield 50 and the impedance Z generated depending on the intensity of the light in the sensor 51 are determined by various conditions, such as the positional relationship between the radiation source (light source) of the light and the electromagnetic shield 50 and the arrangement of objects present on the propagation path of the light from the radiation source to the electromagnetic shield 50, contributing in a complicated manner. Therefore, the intensity of light and the impedance Z irregularly change depending on the installation position of the electromagnetic shield 50 and the time period. That is, the impedance Z generated in the electromagnetic shield 50 randomly changes depending on the time period and the installation position.

As described above, the intensity of light detected by the sensor 51 randomly changes temporally and positionally, whereby the impedance Z of the sensor 51 also randomly changes. At this point, a local complex transmission coefficient in a specific region of the electromagnetic shield 50 is dependent on the impedance Z in the specific region.

Therefore, the electromagnetic wave incident on the electromagnetic shield 50 leaks to the outside of the building after the transmission amplitude and the transmission phase change depending on the transmission time and the transmission position. In other words, the electromagnetic wave incident on the electromagnetic shield 50 is modulated depending on the transmission time and the transmission position and leaks to the outside of the building.

Therefore, when an electromagnetic wave used for wireless communication and an electromagnetic wave (electromagnetic noise) emitted from an electronic device are incident on the electromagnetic shield 50, each of the electromagnetic waves is randomly modulated temporally and positionally by the electromagnetic shield 50. Therefore, information included in the electromagnetic wave becomes different from the original information before the electromagnetic wave is modulated and then is leaked to the outside of the building.

Therefore, the electromagnetic shield 50 can modulate the transmitting electromagnetic wave by disturbance such as light, temperature, and sound naturally present around the electromagnetic shield 50. As a result, even when a person who eavesdrops on the electromagnetic wave outside the building improves the reception sensitivity, the electromagnetic shield 50 can prevent information included in the original electromagnetic wave from being eavesdropped on.

Note that the pairs of conductors 32 connected by the sensors 51 may not be periodically arranged. In addition, the shapes and characteristics of the sensors 51 may not be the same. In this case, the randomness of the modulation on an electromagnetic wave transmitting through the electromagnetic shield 50 can be further increased.

As described above, the electromagnetic shield 50 according to the fifth embodiment includes: one or more substrates 31 each having one or more pairs of conductors 32; and a sensor 51 that couples each of the one or more pairs of conductors 32 and in which the physical properties change due to disturbance naturally present around the substrates. Therefore, the electromagnetic shield 50 can modulate electromagnetic waves without requiring artificial control.

Note that the present disclosure may include a flexible combination of the embodiments, a modification of any component of the embodiments, or an omission of any component in the embodiments within the scope of the disclosure.

### Industrial Applicability

An electromagnetic shield according to the present disclosure can prevent leakage of information included in an electromagnetic wave by modulating the electromagnetic wave using disturbance naturally present around substrates, and is suitable for use as an electromagnetic shield or the like.

### REFERENCE SIGNS LIST

10, 20, 30, 40, 50: electromagnetic shield, 10a, 20a, 30a, 40a, 50a: inner surface, 10b, 20b, 30b, 40b, 50b: outer surface, 11: substrate, 12: conductor, 13: spring, 21: fixing member, 22: propeller, 23: rotation shaft, 23 a: branch shaft, 24: substrate, 25: conductor, 31: substrate, 32: conductor, 33: varactor; 34: support member, 41: environmental power generation element, 51: sensor, D1 to D3: distance, V1, V2: voltage, Z: impedance

1. An electromagnetic shield comprising:
a plurality of substrates each having one or more conductors, the one or more conductors not entirely covering a surface of a corresponding one of the plurality of substrates,
wherein out of the plurality of substrates, substrates adjacent to each other are supported in such a manner that a distance between a conductor of one of the adjacent substrates and a conductor of the other one of the adjacent substrates temporally changes due to disturbance naturally present around the adjacent substrates, and
the electromagnetic shield modulates an electromagnetic wave transmitting through the adjacent substrates.

2. The electromagnetic shield according to claim 1,
wherein the substrates adjacent to each other are supported via an elastic body.

3. The electromagnetic shield according to claim 2,
wherein the elastic body is a spring.

4. The electromagnetic shield according to claim 2,
wherein the elastic body is rubber.

5. The electromagnetic shield according to claim 1,
wherein the disturbance is at least one of vibration, wind, or sound.

6. An electromagnetic shield comprising:
a substrate having one or more conductors; and
a plurality of rotation shafts to each support the substrate around an axial center in a state where the conductors are inclined with respect to a reference plane,
wherein the substrate rotates in such a manner that a distance between a conductor of the substrate and a conductor of a substrate supported by another rotation shaft changes due to disturbance naturally present around the substrate.

7. The electromagnetic shield according to claim 6,
wherein the disturbance is wind.

8. An electromagnetic shield comprising:
one or more substrates each having one or more pairs of conductors; and
a coupling member that couples each of the one or more pairs of conductors, the coupling member having a physical property that temporally changes due to disturbance naturally present around the one or more substrates,
wherein in each of the one or more pairs of conductors, conductors are arranged in such a way as to sandwich the coupling member and face each other, and
each of the conductors is not conducted to other than the coupling member.

9. The electromagnetic shield according to claim 8,
wherein the coupling member is a varactor, and
a capacitance of the varactor changes due to the disturbance naturally present around the one or more substrates.

9. The electromagnetic shield according to claim 9,
wherein the disturbance is a magnetic field.

11. An electromagnetic shield comprising:
one or more substrates each having one or more pairs of conductors; and
a coupling member that couples each of the one or more pairs of conductors, the coupling member having a physical property that temporally changes due to disturbance naturally present around the one or more substrates,
wherein the coupling member is an environmental power generation element, and
a power generation amount of the environmental power generation element changes due to the disturbance naturally present around the one or more substrates.

12. The electromagnetic shield according to claim 11,
wherein the disturbance is any one of light, vibration, or heat.

13. An electromagnetic shield comprising:
one or more substrates each having one or more pairs of conductors; and
a coupling member that couples each of the one or more pairs of conductors, the coupling member having a physical property that temporally changes due to disturbance naturally present around the one or more substrates,
wherein the coupling member is a sensor, and
an impedance of the sensor changes due to the disturbance naturally present around the one or more substrates.

14. The electromagnetic shield according to claim 13,
wherein the disturbance is any one of light, temperature, or sound.
